(19) United States
(12) Patent Application Publication
(10) Pub. No.: US 2024/0152669 A1
(43) Pub. Date: May 9, 2024

(54) PHYSICS-ENHANCED DEEP SURROGATE

(71) Applicants: International Business Machines Corporation, Armonk, NY (US); Massachusetts Institute of Technology, Cambridge, MA (US)

(72) Inventors: Raphael Pestourie, Cambridge, MA (US); Youssef Mroueh, New York, NY (US); Payel Das, Yorktown Heights, NY (US); Steven Glenn Johnson, Arlington, MA (US); Christopher Vincent Rackauckas, Cambridge, MA (US)

(21) Appl. No.: 17/982,996

(22) Filed: Nov. 8, 2022

(51) Int. Cl. G06F 30/27

(52) U.S. Cl. CPC G06F 30/27

(57) ABSTRACT

Surrogate training can include receiving a parameterization of a physical system, where the physical system includes real physical components and the parameterization having corresponding target property in the physical system. The parameterization can be input into a neural network, where the neural network generates a different dimensional parameterization based on the input parameterization. The different dimensional parameterization can be input to a physical model that approximates the physical system. The physical model can be run using the different dimensional parameterization, where the physical model generates an output solution based on the different dimensional parameterization input to the physical model. Based on the output solution and the target property, the neural network can be trained to generate the different dimensional parameterization.

### STATEMENT REGARDING PRIOR DISCLOSURES BY THE INVENTOR OR A JOINT INVENTOR

The following disclosure(s) are submitted under 35 U.S.C. 102(b)(1)(A):

### DISCLOSURE(S)

Physics-enhanced deep surrogates for PDEs, Raphael Pestourie, Youssef Mroueh, Chris Rackauckas, Payel Das, Steven G. Johnson, arXiv:2111.05841v1 [cs.LG] 10 Nov. 2021, pages 1-8.
Data-Efficient Training with Physics-Enhanced Deep Surrogates Raphael Pestourie, Youssef Mroueh, Chris Rackauckas, Payel Das, Steven G. Johnson, Association for the Advancement of Artificial Intelligence (www.aaai.org), 2022, pages 1-6.

### BACKGROUND

The present application relates generally to computers and computer applications, surrogate modeling of physical systems and more particularly to a physics-enhanced surrogate modeling.

### BRIEF SUMMARY

The summary of the disclosure is given to aid understanding of a computer system and method of physics-enhanced deep surrogates, for example, for partial differential equations (PDEs), and not with an intent to limit the disclosure or the invention. It should be understood that various aspects and features of the disclosure may advantageously be used separately in some instances, or in combination with other aspects and features of the disclosure in other instances. Accordingly, variations and modifications may be made to the computer system and/or their method of operation to achieve different effects.

A method, in one aspect, can include receiving a parameterization of a physical system. The physical system can include real physical components. The parameterization can have corresponding target property in the physical system. The method can also include inputting the parameterization into a neural network, where the neural network generates a different dimensional parameterization based on the input parameterization. The different dimensional parameterization can be generated by the neural network for inputting to a physical model that approximates the physical system. The method can also include running the physical model using the different dimensional parameterization, where the physical model generates an output solution based on the different dimensional parameterization input to the physical model. The method can also include, based on the output solution and the target property, training the neural network to generate the different dimensional parameterization.

A system, in an aspect, can include at least one processor. The system can also include a memory device coupled with the at least one processor. The at least one processor can be configured to receive a parameterization of a physical system. The physical system can include real physical components. The parameterization can have corresponding target property in the physical system. The at least one processor can also be configured to input the parameterization into a neural network, where the neural network generates a different dimensional parameterization based on the input parameterization. The neural network generates the different dimensional parameterization for inputting to a physical model that approximates the physical system. The at least one processor can also be configured to run the physical model using the different dimensional parameterization, where the physical model generates an output solution based on the different dimensional parameterization input to the physical model. The at least one processor can also be configured to, based on the output solution and the target property, train the neural network to generate the different dimensional parameterization.

A computer readable storage medium storing a program of instructions executable by a machine to perform one or more methods described herein also may be provided.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 illustrates an example computer or processing system or environment that may implement a system according to one embodiment.

FIG. 2 is a diagram illustrating a surrogate model building in an embodiment.

FIG. 3 is a flow diagram illustrating a method of surrogate modeling in an embodiment.

### DETAILED DESCRIPTION

Systems and methods that can develop one or more surrogate models for one or more physical systems (for example, which can be complex physical systems) are provided. Physical systems can be described by partial differential equations (PDEs) and/or similar models. In one or more embodiments, physics-enhanced deep surrogates (PEDS) can be developed or provided for efficient partial differential equation (PDE)-constrained inverse design.

A surrogate model refers to a model that evaluate solutions, orders of magnitude faster than solving for an original model. For example, surrogate models for PDEs are trained models that evaluate the solution to PDEs orders of magnitude faster than solving for the PDEs directly. Surrogate models are used for large-scale simulation and optimization of complex structures.

Fidelity refers to the accuracy of a model or simulation when compared to the real world. Simulation/model fidelity has to do with how well the simulation/model responds and how the results correspond to what the simulation/model is trying to represent. For example, solving a high-fidelity solver can be computationally expensive, requiring large number of data (and therefore computer storage) and longer time (and therefore more processor cycle time) to compute. Low-fidelity model can be computationally efficient but has reduced accuracy compared to a high-fidelity model.

In one or more embodiments, the systems and/or methods combine a low-fidelity, for example, “coarse” solver or model with a neural network that generates “coarsified” inputs, trained end-to-end to globally match the output of a high-fidelity numerical solver or model. For example, a surrogate model can include physics knowledge to a global surrogate via a differentiable low-fidelity solver. The surrogate model can be built by incorporating physical knowledge in the form of the low-fidelity model (for example, hence referred to as “physics-enhanced”) and using deep learning.

More specifically, a combination of a low-fidelity, explainable physics simulator and a neural network generator can be provided, which is trained end-to-end to globally match the output of an expensive high-fidelity numerical solver. In an embodiment, a system and/or method can consider low-fidelity models derived from coarser discretizations and/or by simplifying the physical equations, which are several orders of magnitude faster than a high-fidelity “brute-force” PDE solver. In an embodiment, the neural network generates an approximate input, which is adaptively mixed with a down-sampled guess and fed into the low-fidelity simulator. In an aspect, by incorporating the physical knowledge from the differentiable low-fidelity model “layer”, the system and/or method can ensure that the conservation laws and symmetries governing the system are respected by the design of a hybrid system disclosed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a new physics-enhanced deep-surrogate algorithm code 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

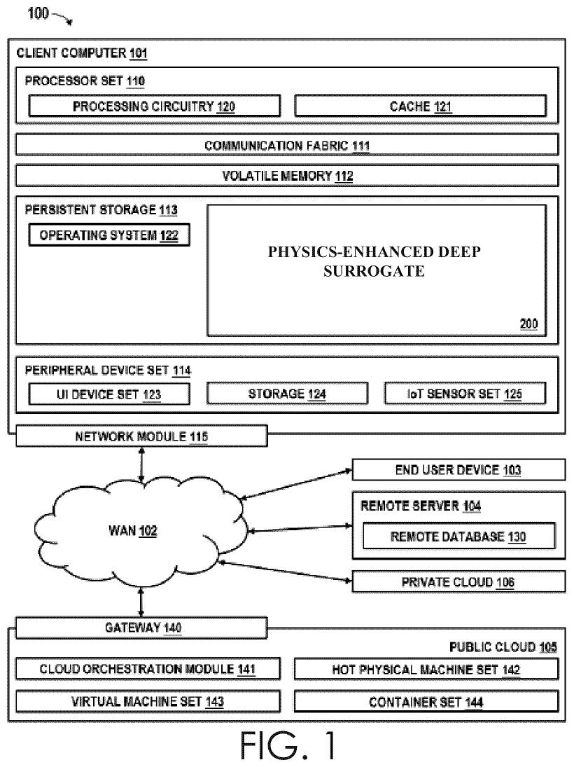

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Various applications of a surrogate model disclosed herein can include, but are not limited to, solving Maxwell's equations, for example, for optical metamaterials, solving a Boltzmann equation, for example, in thermos-electrics, solving for mechanics such as beam, wing design, quantum physics and/or quantum computing solutions, Multiphysics such as photovoltaics, solving for schematics for global atmosphere model such as climate modeling.

A challenge in surrogate modeling is that when the input of the surrogate model is highly dimensional, the number of training points needed to train the model increases exponentially for traditional surrogate techniques and is very large for neural network surrogates. In addition, it may be difficult to incorporate field knowledge in a machine learning model.

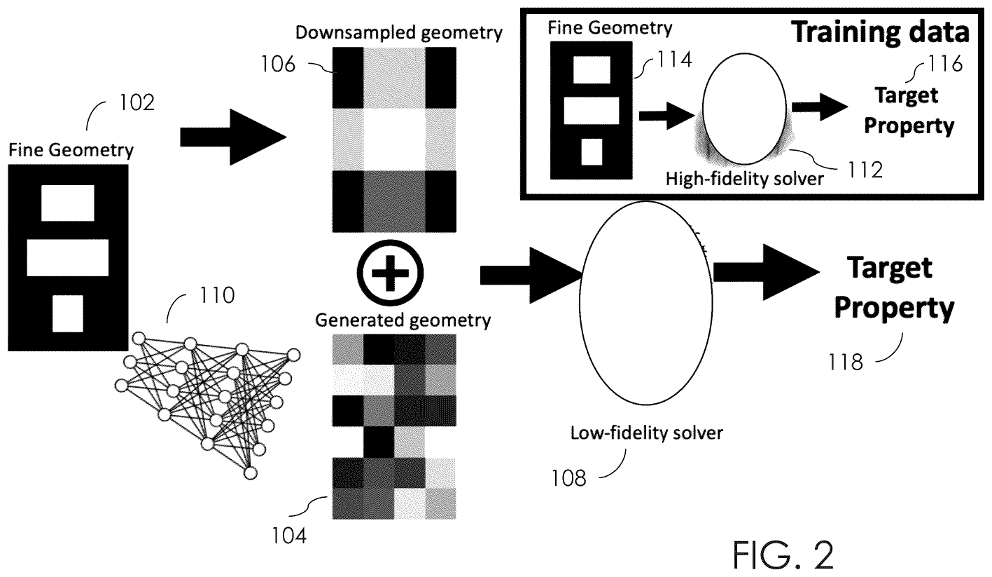

FIG. 2 is a diagram illustrating a surrogate model building in an embodiment. From geometry parameterization 102, a neural network 110 of a surrogate generates a low-fidelity structure 104 that is combined with a down-sampled geometry (for example, down-sampled by pixel averaging) 106 to be fed into a low-fidelity solver 108. In an embodiment, training data can be generated by solving simulations directly on a high-fidelity solver 112. For example, given geometry parametrization 114, a high-fidelity solver 112 provides a solution 116, for example, referred to as “target property” 118. The neural network 110 is trained to generate geometry 104 that maps to the input geometry 102, which when input to a low-fidelity solver 108, the low-fidelity solver 108 would generate a solution 118 that is close as possible to the solution 116 of the high-fidelity solver 112. A training process, for example, involves the components 102, 110, 106, 104, 108 and 118. The training process uses the training data generated by solving simulations directly on a high-fidelity solver 112, for example, the fine geometry 114 and target property 116.

In an aspect, a system and/or method can be provided to train surrogate models for expensive PDE queries or experiments. The system and/or method can incorporate field knowledge about the PDE efficiently inside a machine learning model. There can be multiple levels of domain knowledge incorporated into a surrogate model, for example: low-fidelity solver such that the model respects conservation equations and (time reversal) symmetry by design; knowledge such as down-sampled geometry and symmetry actions on the low-fidelity geometry can be implemented.

A surrogate model disclosed herein can provide for data efficiency; faster inference time or speedups, model explainability, include domain knowledge in the model. A surrogate model can work with various types of low-fidelity solvers, for example: low fidelity by simulating a coarser resolution; low fidelity by solving a simpler but qualitatively similar equation, for example, solving a linearized version of a nonlinear physical model; low fidelity by solving for a different geometry that can be solved very efficiently, for example, solving for infinitely thin layers of aperiodic and arbitrarily patterned materials instead of bulky geometry. A surrogate model can also work with various types of high-fidelity data, for example: the data may have been generated from running expensive numerical simulations; data may have been obtained from precise measurements.

In one or more embodiments, systems and/or methods combine a generative deep learning neural network to create an entire geometry for a low-fidelity solver. In an aspect, a physics-enhanced surrogate model respects governing conservation laws and symmetry by design, which is more trustworthy and explainable.

For example, surrogate modeling takes a parameterization of the physics and/or geometry as input into a neural network that generates a different dimensional parameterization which is input into a low-fidelity solver. The surrogate parameters are trained against high-fidelity data. A neural network architecture and/or device, for example, incorporates a low-fidelity physical model whose inputs are different dimensions than the input to the neural network, and the neural network is trained against high-fidelity data. For example, the neural network learns to map input data to a different dimensional parameterization that can be input into a low-fidelity solver. High-fidelity data can be those generated from solving high-fidelity model. High-fidelity data can be those measured from experimental data. Low-fidelity model can be a coarsified discretization of the high-fidelity model. Low-fidelity model can omit a portion of the physical processes. Low-fidelity model solves a different kind of geometry, for example, collapse some spatial dimensionality of the problem. The physical model can be Multiphysics. The neural network can incorporate a learned-weighted combination of a down-sampled geometry and a generated geometry. The neural network can impose symmetry constraints on the generated parameters.

The systems and/or methods can increase the efficiency of expensive large-scale optimizer (for example, a partial differential equation solver); optimally use partial differential equations solver (for example, Maxwell's equations, thermal transfer-Boltzmann transport equation, mechanics, quantum physics, fluidics); can be used for efficient metamaterial design and may also be used for, but is not limited to, molecule optimization, process optimization; can be used to simulate complex problem with multi-physics; and simulate complex problem with large scale, for example, climate modeling. Examples of numerical solvers (for example, high-fidelity solvers) include, but are not limited to, a circuit model, an integral equation solver, and a partial differential equations solver. The systems and/or methods can be used in a wide variety of physical systems, for example, to build surrogates in a wide variety of physical systems.

By way of example, there can be models at varying levels of fidelity, whether they differ in spatial resolution or in the types of physical processes they incorporate. For example, in fluid mechanics the low-fidelity model could be Stokes flow (neglecting inertia), while the high-fidelity model might be a full Navier-Stokes model (vastly more expensive to simulate), with generator neural network correcting for the deficiencies of the simpler model. Another example can be complex Boltzmann-transport models, where the low-fidelity heat-transport equation can be a diffusion equation. Knowledge of priors can also be introduced in the low-fidelity geometry that is mixed with the neural network generator output. The systems and/or methods in one or more embodiments can provide a data-driven strategy to connect a vast array of simplified physical models with the accuracy of brute-force numerical solvers, offering both more insight and more data efficiency than physics-independent black-box surrogates.

In another embodiment, the neural network incorporated in a surrogate model can take an image of a high-fidelity-structure geometry rather than its parameterization, for example, employing convolutional neural networks to represent a translation-independent “coarsification” and/or a multiresolution architecture. This type of surrogate can then be employed for topology optimization in which “every pixel” is a degree of freedom.

In yet another embodiment, new low-fidelity physics models can be developed that admit ultra-fast solvers, for instance, mapping Maxwell's equations in 3D or 3-dimension onto a simpler (scalar-like) wave equation or mapping the materials into objects that admit especially efficient solvers (such as impedance surfaces or compact objects for surface-integral equation methods).

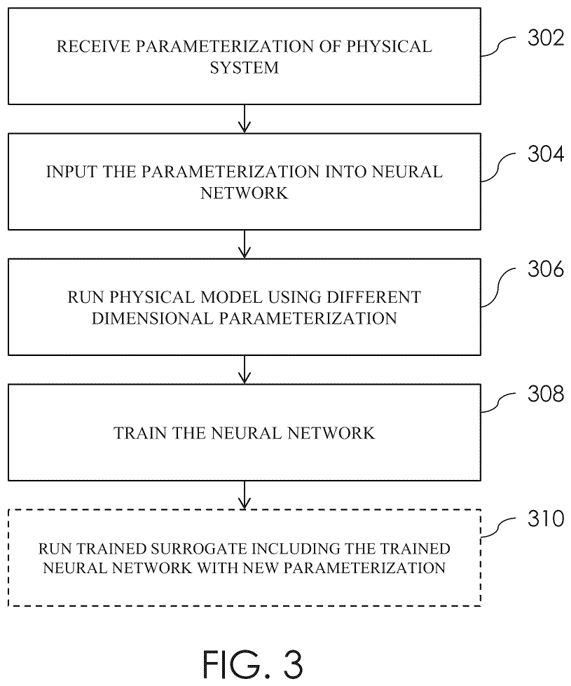

FIG. 3 is a flow diagram illustrating a method of surrogate modeling in an embodiment. The method can be implemented on and run by one or more computer processors, for example, on a computer system or computing environment, for example, shown in FIG. 1. At 302, one or more processors can receive a parameterization of a physical system. The physical system includes real physical components, and the parameterization has corresponding target property in the physical system. For example, a physical system involves a real world physical phenomena. Parameterization includes variables and their values associated with that real world physical phenomena.

At 304, one or more processors can input the parameterization into a neural network. The neural network generates a different dimensional parameterization based on the input parameterization. In an embodiment, the different dimensional parameterization has coarser resolution than the received parameterization of the physical system. In an embodiment, the neural network can impose symmetry constraints on the generated different dimensional parameterization. The different dimensional parameterization can be input to a physical model that approximates the physical system.

At 306, one or more processors can run the physical model using the different dimensional parameterization. The physical model generates an output solution based on the different dimensional parameterization input to the physical model.

At 308, based on the output solution and the target property, one or more processors can train the neural network to generate the different dimensional parameterization.

In one or more embodiments, the training of the neural network can include iterating at least the following: updating parameters of the neural network, for example, by performing backpropagation or gradient descent; running the neural network with the updated parameters for the neural network to generate the different dimensional parameterization; and the running of the physical model using the different dimensional parameterization. Such iterating or iteration can be performed until a threshold convergence in an error between the output solution (for example, target property shown at 118 in FIG. 2) and the target property (for example, target property shown at 116 in FIG. 2) is reached, for example, until the error converges to a threshold minimum or value.

In an embodiment, the method may also include using the trained surrogate, which includes the trained neural network in inference stage. For example, at 310, the trained surrogate including at least the trained neural network and the physical model that approximates the physical system, coupled to the trained neural network, can be run to mimic a high-fidelity physical model such as PDE.

In an embodiment, the target property can be generated by running another physical model, which has higher fidelity than the physical model, for example, a high-fidelity model. For example, the physical model is a low-fidelity model which corresponds to the high-fidelity model. For instance, the physical model simulates in coarser resolution another physical model, which is a high-fidelity model. The physical model can omit a portion of physical processes in another physical model, for example, the high-fidelity model. The physical model can collapse at least one dimension used in another physical model, for example, the high-fidelity model. The physical model can be a discretization (for example, coarsified discretization) of another physical model, for example, the high-fidelity model. In another embodiment, the target property can be obtained or generated from experimental data.

In an embodiment, a down-sampled version of the received parameterization can be obtained, and a weighted combination of the down-sampled version of the received parameterization and the different dimensional parameterization output by the neural network can be input to the physical model. Weights used in the weighted combination can be learned, for example, during the training process of the surrogate and/or the neural network.

In an embodiment, while the neural network generates “equivalent” coarse-grained geometries to the input parameterization or structure, the neural network generated structures or coarse-grained geometries can be qualitatively different.

In one or more embodiments, the systems and/or methods disclosed herein allow machine learning techniques to be applied to inverse design problems such as finding optimal parameters of surrogate models. The systems and/or methods also can implement machine learning techniques in large scale optimization for partial differential equations (PDEs), for example, combine and couple multiple surrogate models in a large-scale framework. The systems and/or methods can provide components in a general framework for inverse design, for example, with problems where decomposition methods apply or where governing equations are known but expensive. The systems and/or methods in one or more embodiments may amortize a learning cost by leveraging field knowledge. In an aspect, a surrogate model built according to one or more embodiments of the systems and/or methods disclosed herein may be at least one order of magnitude faster than solving the PDE problem directly, and may be multiple orders of magnitude faster for solving 3-dimensional (3D) problems. In another aspect, the surrogate model may use at least one order of magnitude less data. The systems and/or methods can work with any type of low fidelity solver, for example: low-fidelity by solving a cheaper but qualitatively similar equation such as heat equation for Boltzmann transport equation (BTE); low-fidelity by simulating a coarser resolution; low fidelity by solving for a different geometry that can be solved very efficiently, such as solving for infinitely thin layers of aperiodic and arbitrarily patterned materials instead of bulky geometry. Yet in another aspect, the systems and/or methods can work in combination with active learning.

The following description provides more technical details of embodiments of the system shown in FIG. 2 and the method shown in FIG. 3.

In mechanics, optics, thermal transport, fluid dynamics, physical chemistry, climate models, crumpling theory, and many other fields, data-driven surrogate models—such as polynomial fits, radial basis functions, or neural networks—can be used as an efficient solution to replace repetitive calls to slow numerical solvers. The reuse benefit of surrogate models, however, may come at a significant training cost, in which a costly high-fidelity numerical solver may need to be evaluated many times to provide an adequate training set, and this cost may rapidly increase with the number of model parameters. The systems and/or methods disclosed herein can increase training-data efficiency: incorporating some knowledge of the underlying physics into the surrogate by training a generative neural network (NN) “end-to-end” with an approximate physics model. This hybrid system is also referred to as a “physics-enhanced deep surrogate” (PEDS). Experiments demonstrate multiple-order-of-magnitude improvements in sample and time complexity on different test problems involving the diffusion equation's flux, the reaction-diffusion equation's flux, and Maxwell's-equations' complex transmission coefficient for optical metamaterials-composite materials whose properties are designed via microstructured geometries. In inverse design (large-scale optimization) of nanostructured thermal materials, chemical reactors, or optical metamaterials, the same surrogate model capturing important geometric aspects of the system may be re-used multiple times, making surrogate models attractive to accelerate computational design.

In one or more embodiments, to obtain an accurate surrogate of a PDE, a systems and/or method disclosed herein can apply a deep neural network to generate a low-fidelity geometry, optimally mixed with the downsampled geometry, which can then be used as an input into an approximate low-fidelity solver and trained end-to-end to minimize the overall error, for example, as shown in FIG. 2. The low-fidelity solver may be the same numerical method as the high-fidelity PDE solver except at a lower spatial resolution, or it may have additional simplifications in the physics (as in the reaction-diffusion example, where the low-fidelity model discards the nonlinear term of the PDE). By design, this low-fidelity solver may yield large errors in the target output, but it is orders of magnitude faster than the high-fidelity model while qualitatively preserving at least some of the underlying physics. The neural network is trained to nonlinearly correct for these errors in the low-fidelity model, but the low-fidelity model “builds in” some knowledge of the physics and geometry that improves the data efficiency of the training. For example, the low-fidelity diffusion model enforces conservation of mass, while the low-fidelity Maxwell model automatically respects conservation of energy and reciprocity, and the system and/or method in one or more embodiments can also enforce geometric symmetries. Incorporating such features augments the “trustworthiness” of the model. The surrogate model built according to a system and/or method disclosed herein can increase accuracy, and reduce the amount of data needed for training data. The system and/or method disclosed herein can also improve the asymptotic rate of learning such that the benefits increase as accuracy tolerance is lowered. In an aspect, adding information from the down-sampled structure increases the accuracy. In another aspect, when the low-fidelity solver layer is very inaccurate, the surrogate model building may gain significant additional benefits by combining it with active-learning techniques. The resulting surrogate (for example, PEDS surrogate) can be faster than its corresponding high-fidelity solver, for example, with two to four orders of magnitude speedup. In yet another aspect, since the neural network can generate a down-sampled or “coarse” version of the geometry (or parameterization), this output can be further examined to gain insight into the fundamental nonlinear physical processes captured by the low-fidelity (lf) solver.

In an embodiment, the surrogate model \tilde{f}(p) (for example, which can include components 110 and 108 shown in FIG. 2) aims to predict f^{hf}(hf(p))—an output property of interest as it would be computed from a computationally intensive high-fidelity (hf) solver f^{hf} (for example, shown at 116 in FIG. 2). The hf solver (for example, shown at 112 in FIG. 2) computes the PDE solution for a high-fidelity geometry hf(p) (for example, shown at 114 in FIG. 2), with p being some parameterization of the geometry (or other system parameters).

In one or more embodiments, the surrogate model can be implemented in the following stages:
1. Given the parameters p of the geometry, a deep generative neural network model (for example, shown at 110 in FIG. 2) yields a grid of pixels describing a low-fidelity geometry. This function is referred to as generator_{N}N(p).
2. The system and/or method also compute a low-fidelity down-sampling (for example, via sub-pixel averaging) of the geometry, denoted downsample(p), for example, shown at 106 in FIG. 2; other prior knowledge can also be incorporated here as well.
3. The system and/or method define G as a weighted combination G(p)=w·generator_{NN}(p)+(1−w)·downsample(p), with a weight wϵ[0,1] (independent of p) that is another learned parameter.
4. If there are any additional constraints and/or symmetries that the physical problem imposes on the geometry, they can be applied as projections P[G]. For example, mirror symmetry can be enforced by averaging G with its mirror image.
5. Given the low-fidelity geometry P[G (p)] (for example, shown at 104, 106), the system and/or method evaluate the low-fidelity solver f^{lf} (for example, shown at 108 in FIG. 2) to obtain the property of interest: \tilde{f}(p)=f^{lf}(P[G(p)]), for example, shown at 118.

In an embodiment, the surrogate model f(p) can be expressed as:

\tilde{f}(p)=f^{lf}(P[w·generator_{NN}(p)+(1−w)·downsample(p)]). (1)

Dataset Acquisition

The surrogate in an embodiment is a supervised model that is trained on a labeled dataset. The system and/or method may further including building the training set by querying the high-fidelity solver with parameterized geometries S={(pᵢ, tᵢ^{hf}), i=1 . . . N}, where pᵢ are parameterized geometries in the training set and tᵢ^{hf}=f^{hf}(hf(pᵢ)). The upfront cost of building the training dataset for developing a supervised surrogate model \tilde{f}(p) can be offset by building some approximate low-fidelity physics knowledge into the surrogate, which can greatly reduce the number N of queries to expensive simulations.

Training Loss

In an embodiment, a basic surrogate training strategy can include minimizing the mean squared error Σ_{(p,t}_{^{hf}}_{)ϵS}|\tilde{f}(p)−t^{hf}|² (for a training set S) with respect to the parameters of the neural network and the weight w. When the data may have outliers, the system and/or method can use a Huber loss.

$${L}_{δ} ( a ) = \{ \begin{matrix}\frac{1}{2} {a}^{2} & for \vert a \vert \leq δ , \\ δ \cdot ( \vert a \vert - \frac{1}{2} δ ) , & otherwise .\end{matrix} \qquad ( 2 )$$

The system and/or method can also employ a more complicated loss function that allows the system and/or method to easily incorporate active-learning strategies. The system and/or method can optimize the Gaussian negative log-likelihood of a Bayesian model,

$$- {\sum }_{( {p}_{i} , {t}_{i}^{hf} ) ∈ S} log {P}_{Θ} ( {t}_{i}^{h f} \vert {p}_{i} ) ∝ {\sum }_{( {p}_{i} , {t}_{i}^{hf} ) ∈ S} [ log σ ( {p}_{i} ) + \frac{{( {t}_{i}^{h f} - \tilde{f} ( {p}_{i} ) )}^{2}}{2 {σ ( {p}_{i} )}^{2}} ] \qquad ( 3 )$$

where P_{θ} is a Gaussian likelihood defined by θ which includes the parameters of the generator model parameters and the combination weight w, and the heteroskedastic “standard deviation” σ(p)>0 is the output of another neural network (trained along with the surrogate model).

Ensemble Model

In one or more embodiments, the system and/or method can also train surrogates that are an ensemble of multiple (for example, 5) independent surrogates. In one or more embodiments, the prediction of the ensemble is the average of the predictions of each individual model.

Stochastic Gradient Descent

In practice, rather than examining the entire training set S at each training step, the system and/or method can follow the standard “batch” approach of sampling a random subset of S and minimizing the expected loss with the Adam stochastic gradient-descent algorithm (for example, but not limited to, via the Flux.jl software in the Julia language).

Adjoint Method

In an embodiment, the low-fidelity solver is a layer of the surrogate model, which is trained end-to-end, therefore, the system and/or method in an embodiment backpropagate its gradient ∇_{g}^{lf} with respect to the low-fidelity geometry input g through the other layers to obtain the overall sensitivities of the loss function. In one or more embodiments, this can be accomplished efficiently using the known “adjoint” methods. Such methods yield a vector-Jacobian product that is then automatically composed with the other layers using automatic differentiation (AD) (for example, but not limited to, via the Zygote.jl software).

For example, the low-fidelity solver layer is differentiable because each pixel of the low-fidelity geometry is assigned to a sub-pixel average of the infinite-resolution structure, which increases accuracy and makes downsample(p) piecewise differentiable. In the same way, hf(p) is differentiable for the high-fidelity geometry.

Experiments on test problems (for example, diffusion, reaction-diffusion, and electromagnetic scattering models) show that a surrogate built according to one or more embodiments disclosed herein, can be more accurate than a “black-box” neural network with limited data (≈103 training points), and reduces the data needed by at least a factor of 100 for a target error of 5%, comparable to fabrication uncertainty. The surrogate model also may learn with a steeper asymptotic power law than black-box surrogates. The surrogate model may provide for a general, data-driven strategy to bridge the gap between a vast array of simplified physical models with corresponding brute-force numerical solvers, offering accuracy, speed, data efficiency, as well as physical insights into the process.

Table 1 illustrates equations of example surrogate models, which approximate three well known PDEs. One is the linear diffusion equation, which has applications in materials science, information theory, biophysics and probability, among others. In this experiment, a surrogate model is trained for the thermal flux, which is a useful design property for thermoelectrics. Another surrogate model is built for the nonlinear reaction-diffusion equation. This PDE is used in chemistry and its surrogates can influence the design of chemical reactors. Yet another surrogate model models the complex transmission of Maxwell's equations through a parameterized structure, which can be used in the design of optical metamaterials. d is the input dimension, i.e., the number of input variables in the surrogate model, which ranges from 10 to 25.

TABLE 1

| | | Model(input |
|---|---|---|
| Equation name | Equation formula | dimension) |
| Diffusion | ∇ · D∇u = s₀ | Fourier(d) |
| Reaction-diffusion | ∇ · D∇u = −ku(1 − u) + s₀ | Fisher(d) |
| D Maxwell (Helmholtz) | ∇²u − ω²εu = s₁ | Maxwell(d) |

The terminology used herein is for the purpose of describing particular embodiments only and is not intended to be limiting of the invention. As used herein, the singular forms “a”, “an” and “the” are intended to include the plural forms as well, unless the context clearly indicates otherwise. As used herein, the term “or” is an inclusive operator and can mean “and/or”, unless the context explicitly or clearly indicates otherwise. It will be further understood that the terms “comprise”, “comprises”, “comprising”, “include”, “includes”, “including”, and/or “having,” when used herein, can specify the presence of stated features, integers, steps, operations, elements, and/or components, but do not preclude the presence or addition of one or more other features, integers, steps, operations, elements, components, and/or groups thereof. As used herein, the phrase “in an embodiment” does not necessarily refer to the same embodiment, although it may. As used herein, the phrase “in one embodiment” does not necessarily refer to the same embodiment, although it may. As used herein, the phrase “in another embodiment” does not necessarily refer to a different embodiment, although it may. Further, embodiments and/or components of embodiments can be freely combined with each other unless they are mutually exclusive.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
receiving a parameterization of a physical system, the physical system including real physical components, the parameterization having corresponding target property in the physical system;
inputting the parameterization into a neural network, wherein the neural network generates a different dimensional parameterization based on the input parameterization, the different dimensional parameterization for inputting to a physical model that approximates the physical system;
running the physical model using the different dimensional parameterization, wherein the physical model generates an output solution based on the different dimensional parameterization input to the physical model; and
based on the output solution and the target property, training the neural network to generate the different dimensional parameterization.

2. The method of claim 1, wherein the training of the neural network includes iterating at least:
updating parameters of the neural network;
running the neural network with the updated parameters for the neural network to generate the different dimensional parameterization; and
the running of the physical model using the different dimensional parameterization;
wherein the iterating is performed until a threshold convergence in an error between the output solution and the target property is reached.

3. The method of claim 1, wherein the target property is generated by running another physical model, which has higher fidelity than the physical model.

4. The method of claim 3, wherein the physical model simulates in coarser resolution said another physical model.

5. The method of claim 4, wherein the physical model omits a portion of physical processes in said another physical model.

6. The method of claim 4, wherein the physical model collapses at least one dimension used in said another physical model.

7. The method claim 3, wherein the physical model is a discretization of said another physical model.

8. The method of claim 1, wherein the target property is generated from experimental data.

9. The method of claim 1, wherein the different dimensional parameterization has coarser resolution than the received parameterization of the physical system.

10. The method of claim 1, further including obtaining a down-sampled version of the received parameterization, and wherein weighted combination of the down-sampled version of the received parameterization and the different dimensional parameterization output by the neural network is input to the physical model.

11. The method of claim 10, wherein weights used in the weighted combination are learned.

12. The method of claim 1, wherein the neural network imposes symmetry constraints on the generated different dimensional parameterization.

13. A system comprising:
at least one processor; and
a memory device coupled with the at least one processor;
the at least one processor configured to at least:
receive a parameterization of a physical system, the physical system including real physical components, the parameterization having corresponding target property in the physical system;
input the parameterization into a neural network, wherein the neural network generates a different dimensional parameterization based on the input parameterization, the different dimensional parameterization for inputting to a physical model that approximates the physical system;
run the physical model using the different dimensional parameterization, wherein the physical model generates an output solution based on the different dimensional parameterization input to the physical model; and
based on the output solution and the target property, train the neural network to generate the different dimensional parameterization.

14. The system of claim 13, wherein the device is caused to train the neural network by at least iterating:
updating parameters of the neural network;
running the neural network with the updated parameters for the neural network to generate the different dimensional parameterization; and
running the physical model using the different dimensional parameterization;
wherein the iterating is performed until a threshold convergence in an error between the output solution and the target property is reached.

15. The system of claim 13, wherein the target property is generated by running another physical model, which has higher fidelity than the physical model.

16. The system of claim 15, wherein the physical model simulates in coarser resolution said another physical model.

17. The system of claim 13, wherein the processor is further configured to obtain a down-sampled version of the received parameterization, and wherein weighted combination of the down-sampled version of the received parameterization and the different dimensional parameterization output by the neural network is input to the physical model.

18. A computer program product comprising a computer readable storage medium having program instructions embodied therewith, the program instructions readable by a device to cause the device to:
receive a parameterization of a physical system, the physical system including real physical components, the parameterization having corresponding target property in the physical system;
input the parameterization into a neural network, wherein the neural network generates a different dimensional parameterization based on the input parameterization, the different dimensional parameterization for inputting to a physical model that approximates the physical system;
run the physical model using the different dimensional parameterization, wherein the physical model generates an output solution based on the different dimensional parameterization input to the physical model; and
based on the output solution and the target property, train the neural network to generate the different dimensional parameterization.

19. The computer program product of claim 18, wherein the device is caused to train the neural network by at least iterating:
updating parameters of the neural network;
running the neural network with the updated parameters for the neural network to generate the different dimensional parameterization; and
running the physical model using the different dimensional parameterization;
wherein the iterating is performed until a threshold convergence in an error between the output solution and the target property is reached.

20. The computer program product of claim 18, wherein the device is further caused to obtain a down-sampled version of the received parameterization, and wherein weighted combination of the down-sampled version of the received parameterization and the different dimensional parameterization output by the neural network is input to the physical model.
